(19) United States
(12) Patent Application Publication
(10) Pub. No.: US 2025/0038698 A1
(43) Pub. Date: Jan. 30, 2025

(54) STRUCTURAL ELEMENT IN THE FORM OF A PARTICULAR SANDWICH-LIKE FACADE PANEL AND METHOD FOR PRODUCING SUCH A STRUCTURAL ELEMENT

(71) Applicant: sedak GmbH & Co. KG, Gersthofen (DE)

(72) Inventor: Fritz SCHLÖGL, Gersthofen (DE)

(21) Appl. No.: 18/784,699

(22) Filed: Jul. 25, 2024

(30) Foreign Application Priority Data
Jul. 28, 2023 (DE) 102023120206.5

(51) Int. Cl. H02S 20/26; E04F 13/072; E04F 13/08; H01L 31/048

(52) U.S. Cl. CPC H02S 20/26; E04F 13/072; E04F 13/0866; H01L 31/0488

(57) ABSTRACT

The invention relates to a structural element (1) in the form of a particularly sandwich-like facade panel. The structural element (1) comprises a substrate in the form of a monolithic glass plate (2) having an upper side which forms the outer face of the structural element (1) realized in particular as a facade panel. The structural element (1) further comprises a plurality of photovoltaic modules (3) arranged in a row or in an array. The invention particularly provides for the photovoltaic modules (3) to be materially laminated onto an underside of the substrate (2) opposite from the upper side particularly in the course of an autoclave process.

The present invention relates to a structural element in the form of a particularly sandwich-like facade panel with an optimized exterior surface.

Facade panels for use in the construction industry, in particular for roofing and facade cladding, are generally known from the prior art. They usually consist of two outer panels made of sheet metal or PVC, between which there is a sandwiched insulating layer made from, for example, polyurethane foam.

For example, the WO 2004/009929 A1 publication describes an insulating panel. The panel known from this prior art consists of a pair of thin sandwiched metal sheets with an insulating layer in between.

The EU Buildings Directive, in force since 2021, requires a largely balanced energy balance (nearly zero energy) for new buildings. As a result, roof and facade surfaces are increasingly being used to produce energy. Solar technology and photovoltaics are particularly frequently used in this respect.

These products are already quite advanced. Yet these products have the disadvantage of primarily dominating the external appearance of the facade or the roof.

Besides the described technology, energy is also obtained from wind turbines. Primarily prevailing here are installations which take advantage of wind power by using various types of rotors. While the use of such installations on roofs or facades is possible and conceivable, these installations also have a substantial effect on the building's appearance.

On the other hand, photovoltaic modules are used in numerous places today such that building facades are also potential installation sites for photovoltaic systems, also referred to as “BIPV applications” in this context. BIPV is the abbreviation for the English term of “building-integrated photovoltaics.” In German, sometimes the abbreviation of the German term, GIPV, is also used.

With such BIPV applications, it is not necessarily just a question of the utilized photovoltaic modules producing electricity as efficiently as possible. Rather, aesthetic aspects also play a crucial role in the approval of building projects when integrating photovoltaic modules into building facades.

The general aim is reducing the ecological footprint in the building sector field. An environmentally friendly on-site use of renewable resources can contribute to that on the one hand while there is also an environmentally conscious overall view of new construction or building longevity on the other hand. This applies all the more so in the industrial sector which has a greater environmental impact, for example due to the construction of large factory buildings.

Specifically, the term building-integrated photovoltaics (BIPV) is used when referring to solar modules not placed on the roof but rather integrated into the building envelope. While BIPV modules offer some advantages, they also need to fulfill specific requirements.

In contrast to conventional solar modules, BIPV modules are themselves a component part of a building, either as roofing or as part of the facade.

Generating solar electricity is often not the sole function of BIPV modules. For example, they offer protection from the weather (rain, snow and sun), provide cooling as a building's curtain-wall facade, or they can let through natural light as semi-transparent solar modules, which makes additional lighting superfluous and also provides visual accents. They moreover serve as design elements enhancing the building aesthetically. BIPV modules are frequently used:
as in-roof modules
as facade PV modules,
for solar carports or solar terraces, and
as parking lot canopies.

In the broader sense, solar roof tiles are also part of the building-integrated photovoltaics sector. However, due to the relative high costs and vulnerability to failure, solar roof tiles are only rarely used in the private sector—for example should protected historic monuments leave no other viable options.

In practice, it has thus long been known that solar radiation can be used to generate electricity on the one hand as well as heat on the other, or can be used systematically to reduce use of external energy sources and conserve resources. Insofar, one can generally speak of a solar energy production element which for instance includes photovoltaic modules or photovoltaic panels (PV modules/PV panels for short) for producing electricity from solar radiation or even solar thermal modules for utilizing the heat of solar radiation. The following will refer to a photovoltaic module in this context for short. This is also to include combined elements which both produce electricity via photovoltaic panels (referred to in the following as “PV panels” for short) as well as specifically utilize the heat via solar thermal energy.

Heat pumps are also frequently integrated into a building's energy usage in order to reduce the consumption of external resources as much as possible.

A further aspect with regard to an improved ecological footprint of a building is, on the one hand, keeping the construction site turnaround time as short as possible during building construction and yet, on the other hand, also render buildings which will last as long as possible in order to ward off resource-consuming restoration work for as long as possible.

Worthwhile to consider against this background is, for example, using prefabricated elements for the provisioning of a building, most notably a facade.

On the other hand, it is the stated goal of many architects and designers to implement glass facades and all types of glass walls or glass components over the largest possible surface areas. Yet a conflict arises if a facade panel is to be as spatially large as possible on the one hand and, on the other, is to comprise a photovoltaic module since conventional, commercially available photovoltaic modules cannot exceed a specific dimension.

With that in mind, the present invention is based on the task of providing a facade element for the constructing of a building facade which enables environmentally friendly and quick construction of a building. The constructed facade should allow the longest possible longevity and ideally also a resource-efficient operation of the building.

The invention is furthermore based on the task of providing a corresponding building facade which is able to be manufactured easily, quickly and in an environmentally friendly manner, ensures longevity, and preferably also enables a resource-efficient operation of the building.

The invention in particular solves this task with the subject matter of independent claim 1, whereby advantageous developments of the invention are indicated in the dependent claims.

Accordingly, the invention in particular relates to a structural element in the form of a particularly sandwich-like facade panel, wherein the structural element comprises a substrate in the form of a monolithic glass plate. The monolithic glass plate has an upper side which forms the outer face of the structural element realized in particular as a facade panel.

The structural element further comprises a plurality of photovoltaic modules arranged in a row or in an array. The photovoltaic modules are materially bonded, and in particular laminated, to an underside of the substrate opposite from the upper side.

Specifically, the photovoltaic modules can be laminated onto an underside of the substrate opposite from the upper side in the course of a particularly temperature-controlled vacuum process and preferably by means of an autoclave process.

The inventive approach thus provides for using simplified PV modules; i.e. modules only having a simple thin cover glass which are fully connected as well as tested, and laminating them onto an oversized, particularly coated substrate plate in an autoclave process. The pre-connected modules are thus no longer subject to damage since the soldered PV cells are already fully encapsulated. Additionally, the individual modules can be individually connected and pursuant to electrical engineering standards in exactly the same manner as separate unconnected modules.

Known cell modules are thereby just as suitable for laminating onto the substrate glass as thin-film modules.

The term photovoltaic (PV) herein generally denotes the process of converting solar energy into (usable) electricity.

Preferably also particularly suitable for the invention is the technology of flexible thin-film solar modules, in particular with amorphous silicon cells, which are thin and flexible (bendable) in at least one direction. These are also referred to as foil-like. These foil-like PV elements are thus particularly suited to being combined with or connected to the likewise thin, flexible and bendable surface structures preferably made of foils or fabrics.

Accordingly, design variants provide for realizing the substrate implemented in the form of a monolithic glass plate as a curved pane of glass having a predefined or definable bending radius.

However, other flexible solar cells, solar (cell) modules and elements can for example also be used, e.g. so-called CIS or CIGS modules, Grätzel cells, organic solar cells, etc.

Producing oversized BIPV modules for challenging architecture is not possible without the newly developed method or present invention respectively. The PV element sizes can be adapted to the joint grid of the large facade glass. In particular, the invention allows for free design of the energy-generating facade elements, preferably tailored to the design requirements of sophisticated architecture, for example in prestigious public or private buildings.

Each photovoltaic module of the inventive facade panel comprises at least one solar cell having a front side and a rear side facing a base plate of the photovoltaic module. The front side of the solar cell is connected to an electrically conductive layer arranged on the base plate of the module, wherein the base plate consists of at least one electrically insulating layer with a first structured and electrically conductive layer on the side opposite from the solar cell which is electrically connected to the front side of the solar cell. A second structured and electrically conductive layer which is electrically connected to the rear side of the solar cell is arranged on the opposite side of the insulating layer.

Each photovoltaic module preferably comprises a transparent layer, particularly a glass pane, covering the at least one solar cell, via which the photovoltaic module is connected/laminated to the underside of the substrate in the course of an autoclave process.

The in particular oversized substrate glass is preferably provided with a special coating which allows at least 80% of the incident light, preferably at least 85% and even more preferentially at least 90%, to pass through the glass plate.

The surface coating is in particular designed such that a structure of the photo-voltaic module arrangement and/or the photovoltaic modules are not or at least not entirely visible to the human observer from the outside; i.e. when viewing the upper side of the substrate realized in the form of a monolithic glass plate. This thus creates the impression of an oversized glass paneling which, technically speaking, however, consists of numerous individual standard PV modules.

The monolithic glass plate serving as the substrate preferably contains 60-75% by weight of silicon oxide, 0-10% by weight of AL₂O₃, 0-5% by weight of B₂O₃, 5-15% by weight of CaO, 0-10% by weight of MgO, 5-20% by weight of Na₂O, 0-10% by weight of K₂O, 0-5% by weight of BaO, >0.2-0.4 by weight of SO₃, 0-0.015% by weight of Fe₂O₃ and a FeO to Fe₂O₃ ratio of 0.2 to 0.4, particularly preferentially approximately 0% by weight of B₂O₃ and approximately 0% by weight of BaO.

The substrate realized in the form of a monolithic glass plate is in particular realized as a fully tempered pane of glass or as a plate of semi-tempered glass. This construction creates—by virtue of the glass pane made of tempered glass—a statically self-supporting structure.

According to implementations of the inventive structural element, the substrate realized in the form of a monolithic glass plate and the plurality of photovoltaic modules arranged in a row or in an array are combined into one statically self-supporting unit, and preferably in such a manner that the structural element only needs to be held on one side or at maximum two sides when installed.

This statically self-supporting property of the ballistic block is thereby achieved by the PV modules being laminated onto the rear side of the substrate realized in the form of a monolithic glass plate while the substrate realized in the form of a monolithic glass plate is not made of float glass but rather consists of tempered glass, thereby providing the statically self-supporting property of the structural element.

In the building trade, the term “statically self-supporting” is to be understood as a structure which assumes the supporting function. There is no distinction between components and parts solely under bending/torsion load and those under shear load. Rather, all the parts act statically as shells and absorb introduced forces as a whole. Nor are any frame structures, etc., necessary to hold the ballistic block, or the glass panes of the ballistic block respectively, as the ballistic block as such is statically self-supporting.

The rigidity which is necessary particularly in order to realize the structural element as statically self-supporting can in particular only be achieved by using tempered glass for the substrate of the structural element realized in the form of a monolithic glass plate. It has thereby been shown that a structural element made of float glass does not exhibit any self-supporting property in the static sense.

A surface structure having a mean roughness index Ra of 2.0 μm to 3.5 μm can be formed on the upper side of the monolithic glass plate. This mean roughness index achieves particularly high light diffusion along with simultaneously high energy transmission.

As an outer shell, the inventive facade element can furnish weather protection for the warm area of the building, particularly in cold facades, and can moreover serve as a distinctive facade design element. Because the facade element can also be oversized, a visually cohesive appearance can be achieved. Even in the case of unusual facade geometries, the design of the modules and their cells can be perfectly adapted to the angles of the building.

A surface coating is preferably provided on the upper side and/or underside of the substrate realized in the form of a monolithic glass plate which is designed to allow at least 80% of the incident sunlight striking the upper side, preferably at least 85% and even more preferentially at least 90%, to pass through the glass plate.

The surface coating is in particular designed such that a structure of the photo-voltaic module arrangement and/or the photovoltaic modules are not or at least not entirely visible to the human observer from the outside; i.e. when viewing the upper side of the substrate realized in the form of a monolithic glass plate from the top.

This thereby enables selectively realizing transparent facade elements with a discretionary degree of transparency and highest solar yields, colored facade elements with inconspicuous PV cells and highest energy yields, or high-quality, homogeneous, single-colored facade elements without visible PV technology.

Alternatively or additionally thereto, a foil layer with an in particular temperature-activatable adhesive layer and preferably a surface coating can be provided on the underside of the substrate realized in the form of a monolithic glass plate which is designed to allow at least 80% of the incident sunlight striking the upper side, preferably at least 85% and even more preferentially at least 90%, to pass through the glass plate.

Particularly able to be realized with the invention are oversize BIPV facade elements to fit the currently producible facade glass sizes of 20 m×3.6 m.

The invention further relates to a method for producing a structural element of the above-cited inventive type; i.e. producing a structural element in the form of a particularly sandwich-like facade panel. The method in particular comprises the following method steps:
providing a monolithic glass plate having an upper side which will form the outer face of the structural element realized in particular as a facade panel;
providing a plurality of photovoltaic modules arranged in a row or in an array; and
laminating the photovoltaic modules onto an underside of the monolithic glass plate opposite from the upper side in an autoclave process.

It is thereby in particular provided for the monolithic glass plate to have a surface area of at least 5 m² and preferably at least 10 m².

The photovoltaic modules are in particular autonomous modules which as such are already operatively connected and in particular tested, whereby each photovoltaic module is in particular implemented as a fully encapsulated module.

The following will reference the accompanying drawings in describing an exemplary embodiment of the invention in greater detail.

Shown are:

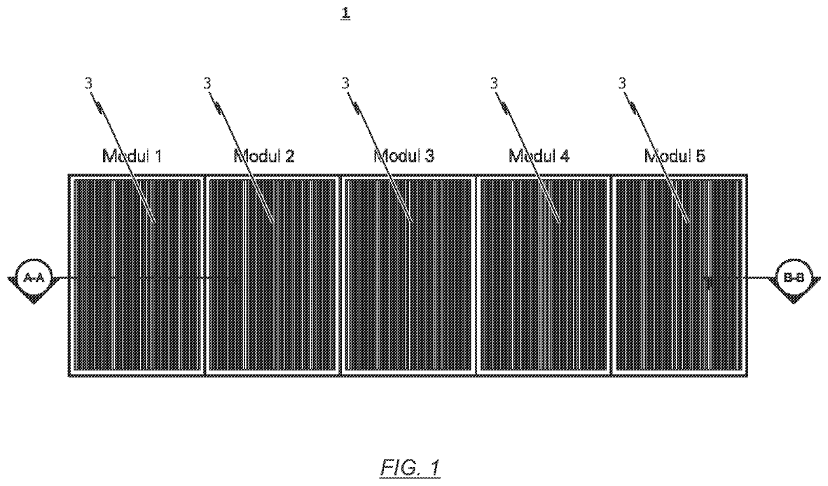

FIG. 1 a schematic and top view of a first exemplary embodiment of the structural element according to the invention, wherein the structural element is realized as a BIPV facade panel; and

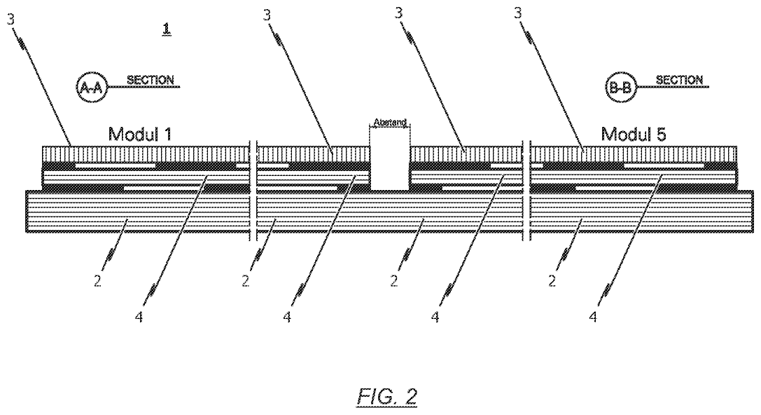

FIG. 2 a schematic and sectional view along the A-A and B-B line in FIG. 1 of the exemplary embodiment of the inventive structural element.

Building-integrated photovoltaics which make use of “unused” exterior building surfaces to produce sustainable electricity is by now a growing market. In order to integrate these wall-mounted photovoltaic modules into the building design, it is currently common practice to “hide” the actual photovoltaic module by means of different translucent colored coatings.

In contrast, the aim of the present invention is to specify oversized photovoltaic modules which fit the currently producible facade glass sizes of 20 m×3.6 m.

Building-integrated photovoltaics relate to structural elements which, in addition to producing electricity, also assume “conventional” functions such as thermal insulation, wind and weather protection or even architectural functions. Particularly in the facade, building-integrated photovoltaic components fulfill tasks that go well beyond producing electricity.

The inventive facade elements with fully integrated solar modules can be used in transparent and non-transparent areas but also as rear-ventilated curtain-wall facades.

Individual colored and/or surface-textured facade elements of the present invention realized as BIPV modules can in particular be very suitable as architectural design elements for buildings or entire urban districts.

The facade elements of the present invention realized as BIPV modules can be produced efficiently and in large quantities in so-called plate laminators. This process is particularly gentle and prevents damaging the sensitive soldered silicon elements of the PV modules. However, the special process necessitates an expensive acquisition of fully automatic plate laminators on the one hand and, on the other, due to their availability, the size able to be produced is limited to a maximum of 2 m×3 m.

For oversize glass, for example facade glass measuring 20 m×3.6 m, the so-called autoclave process is often used for joining. However, the autoclave process which is used for joining glass of such sizes is not suitable for producing PV modules since the sensitive semiconductor cells of the PV modules would thereby break.

Even assembling individual arrangements without suitably available automation is highly risky for the sensitive cells. Thus, even minor damage to just one cell of a PV module during production would mean the total loss of an entire, precision-produced, oversized and expensive module.

Nor is it additionally possible to choose PV module dimensions of arbitrarily large size as the respective output of such a module would be too high. There are no compatible connector cables or inverters for such modules. That means there are also electrotechnical limits on feasibility.

Even so-called thin-film modules are only produced fully automatically in one uniform size in a highly complex process. Although thin-film modules are less sensitive with respect to the lamination process, production size is also extremely limited in terms of system technology to sizes of approximately 1.6 m×0.64 m.

Accordingly, there is a need, which the present invention fulfills, to provide a facade panel with building-integrated photovoltaics, whereby architecturally desired oversized dimensions, e.g. 20 m×3.6 m, are able to be realized.

FIG. 1 shows a first exemplary embodiment of the structural element 1 according to the invention in a schematic and top view, wherein the structural element 1 is realized as a BIPV facade panel, while FIG. 2 shows the exemplary embodiment of the inventive structural element 1 along the A-A and B-B line in FIG. 1 in a schematic and sectional view.

Briefly summarized, this relates to a structural element 1 in the form of a particularly sandwich-like facade panel, wherein the structural element 1 comprises a substrate in the form of a monolithic glass plate 2. The glass plate 2 has an upper side which forms the outer face of the structural element 1 particularly realized as a facade panel.

The structural element 1 further comprises a plurality of photovoltaic modules 3 arranged in a row or in an array, wherein the photovoltaic modules 3 are laminated to an underside of the substrate 2 opposite from the upper side in the course of an autoclave process.

Each photovoltaic module 3 comprises at least one solar cell having a front side and a rear side facing a base plate of the photovoltaic module 3, wherein the front side of the solar cell is connected to an electrically conductive layer arranged on the base plate of the photovoltaic module 3, wherein the base plate consists of at least one electrically insulating layer having a first structured and electrically conductive layer on the side opposite from the at least one solar cell which is electrically connected to the front side of the solar cell, and wherein a second structured and electrically conductive layer which is electrically connected to the rear side of the at least one solar cell is arranged on the opposite side of the insulating layer.

Each photovoltaic module 3 comprises a transparent layer, particularly a glass pane 4, covering the at least one solar cell, via which the photovoltaic module 3 is materially bonded to the underside of the substrate 2.

The photovoltaic modules 3 are in particular autonomous modules which as such are already operatively connected and in particular tested. In particular, each photovoltaic module 3 is implemented as a fully encapsulated module.

The invention is not limited to the embodiment shown in the drawings but rather yields from an integrated overall consideration of all the features disclosed herein.

Particularly conceivable in this context is for the structural element 1 shown schematically in FIG. 1 and FIG. 2 to be provided with a surface coating on the upper side and/or underside of the substrate 2 realized in the form of a monolithic glass plate 2 which is designed to allow at least 80% of the incident sunlight striking the upper side, preferably at least 85% and even more preferentially at least 90%, to pass through the glass plate 2.

The surface coating can in particular be designed such that a structure of the arrangement of photovoltaic modules 3 and/or the photovoltaic modules 3 are not or at least not entirely visible to the human observer from the outside; i.e. when viewing the upper side of the substrate 2 realized in the form of a monolithic glass plate 3 from the top.

### LIST OF REFERENCE NUMERALS

1 structural element/facade element
2 substrate/glass plate
3 PV module
4 cover layer/glass plate of PV module

1. A structural element in the form of a sandwich-like facade panel, wherein the structural element comprises:
a substrate in the form of a monolithic glass plate having an upper side which forms an outer face of the structural element; and
a plurality of photovoltaic modules arranged in a row or in an array, wherein the photovoltaic modules are laminated onto an underside of the substrate opposite from the upper side.

2. The structural element according to claim 1, wherein the photovoltaic modules are laminated onto the underside of the substrate by a temperature-controlled vacuum process.

3. The structural element according to claim 1, wherein the photovoltaic modules are laminated onto the underside of the substrate by an autoclave process.

4. The structural element according to claim 1, wherein each photovoltaic module comprises at least one solar cell having a front side and a rear side facing a base plate of the photovoltaic module, wherein the front side of the solar cell is connected to an electrically conductive layer arranged on the base plate of the photovoltaic module, wherein the base plate includes at least one electrically insulating layer having a first structured and electrically conductive layer on a side opposite from the solar cell which is electrically connected to the front side of the solar cell, and wherein a second structured and electrically conductive layer, which is electrically connected to the rear side of the at least one solar cell, is arranged on an opposite side of the electrically insulating layer.

5. The structural element according to claim 4, wherein each photovoltaic module comprises a transparent layer, wherein the transparent layer includes a glass pane covering the at least one solar cell, via which the photovoltaic module is bonded to the underside of the substrate.

6. The structural element according to claim 1, wherein the photovoltaic modules are autonomous modules which are operatively connected or capable of being operatively connected and tested.

7. The structural element according to claim 1, wherein each photovoltaic module is a fully encapsulated module.

8. The structural element according to claim 1, wherein a surface coating is provided on the upper side and the underside of the substrate which is configured to allow at least 80% of incident sunlight striking the upper side to pass through the glass plate, wherein the surface coating is configured such that a structure of the photovoltaic module arrangement and/or the photovoltaic modules are not or at least not entirely visible to a human observer from an outside environment when viewing the upper side of the substrate from a top location.

9. The structural element according to claim 1, wherein a foil layer with a temperature-activatable adhesive layer and a surface coating is provided on the underside of the substrate which is configured to allow at least 80% of incident sunlight striking the upper side to pass through the glass plate.

10. The structural element according to claim 1, wherein the substrate has a surface area of at least 4 m².

11. The structural element according to claim 1, wherein the substrate is a curved pane of glass having a predefined or definable bending radius; and wherein the substrate is a fully tempered pane of glass or a plate of semi-tempered glass.

12. The structural element according to claim 1, wherein the substrate and the plurality of photovoltaic modules are arranged in a row or in an array and are combined into one statically self-supporting unit such that the structural element only needs to be held on one side thereof or at maximum two sides thereof when installed.

13. A method for producing a structural element in the form of a sandwich-like facade panel, wherein the method comprises the following method steps:
providing a monolithic glass plate having an upper side configured to form an outer face of the structural element;
providing a plurality of photovoltaic modules arranged in a row or in an array; and
laminating the photovoltaic modules onto an underside of the monolithic glass plate opposite from the upper side by an autoclave process.

14. The method according to claim 13, wherein the monolithic glass plate has a surface area of at least 4 m².

15. The method according to claim 13, wherein the photovoltaic modules are autonomous modules which are operatively connected and tested, wherein each photovoltaic module is a fully encapsulated module.
